(19) United States
(12) Patent Application Publication
(10) Pub. No.: US 2007/0161254 A1
(43) Pub. Date: Jul. 12, 2007

(54) METHOD OF FORMING A PASSIVATION LAYER OF A SEMICONDUCTOR DEVICE

(76) Inventor: Tae Young Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,253

(22) Filed: Dec. 26, 2006

(30) Foreign Application Priority Data
Dec. 29, 2005 (KR) 10-2005-0133240

(51) Int. Cl. H01L 21/31; H01L 21/469; H01L 21/4763

(52) U.S. Cl. 438/778; 438/637; 438/787

(57) ABSTRACT

Lowering the temperature at which an oxide layer is formed produces a passivation layer with improved adhesion characteristics and crack resistance. The method of forming the passivation layer includes first forming an intermetal dielectric layer over a lower metal layer of a semiconductor device. A via is formed in the intermetal dielectric layer. A metal line is formed on the via. A passivation layer is formed over the substrate including the metal line, the passivation layer being formed at a temperature of 300˜350° C. by a high density plasma chemical vapor deposition process.

The present application claims priority under 35 U.S.C. 119 and 35 U.S.C. 365 to Korean Patent Application No. 10-2005-0133240 (filed on Dec. 29, 2005), which is hereby incorporated by reference in its entirety.

### BACKGROUND

A semiconductor manufacturing process includes a Front End of the Line (FEOL) process forming transistors over a silicon substrate, and a Back End of the Line (BEOL) process forming lines.

A lining technology is a technology that implements on silicon a path for power supply and signal transfer, which constitutes a circuit connecting individual transistors in a semiconductor integrated circuit (IC).

Since semiconductor integrated circuits may be manufactured in a multi-layered structure, an IC device patterned on one layer and an IC device on another layer need to be connected to each other. Therefore, in the lining process, etching is performed to form a via hole down to a lower IC device for the mutual connection through a dielectric material.

After the via hole is formed by etching, the via hole is filled with a conductive material, for example, tungsten or aluminum to form a conductive via between a lower layer and a metal line or wiring layer sequentially deposited and patterned over the lower layer. A plurality of wiring layers are formed by repeating such a process. Finally, a passivation layer is formed over the substrate to protect a surface of the completed device.

The passivation layer used to protect the semiconductor device is formed by forming an oxide layer and then a nitride layer. However, the nitride layer is easily cracked because of the nature of nitride. For this reason, when a strong external stress is applied to the passivation layer, cracks may occur in the layer. A tensile stress is especially damaging, and may detach the passivation layer from the substrate.

### SUMMARY

Accordingly, embodiments relate to a method of forming a passivation layer of a semiconductor device that substantially obviates one or more problems due to limitations and disadvantages of the related art.

Embodiments relate to a method of forming a passivation layer of a semiconductor device which improves the adhesion characteristics of the passivation layer and prevents cracks therein by adjusting the temperature at which an oxide layer is formed in formation of the passivation layer.

Additional advantages, objects, and features of the embodiments will be set forth in part in the description which follows and in part will become apparent to those having ordinary skill in the art upon examination of the following or may be learned from practical expericence with the embodiments. The objectives and other advantages of the embodiments may be realized and attained by the structure particularly pointed out in the written description and claims hereof as well as the appended drawings.

Embodiments relate to a method of forming a passivation layer of a semiconductor device, including first forming an intermetal dielectric layer over a lower metal layer of a semiconductor device. A via is formed in the intermetal dielectric layer. A metal line is formed on the via. A passivation layer is formed over the substrate including the metal line, the passivation layer being formed at a temperature of 300˜350° C. by a high density plasma chemical vapor deposition process.

The passivation layer may be an oxide (SiO₂) layer. The temperature may be adjusted by controlling a cooling gas flow to a wafer in the high density plasma chemical vapor deposition process. The cooling gas flow of the wafer is 4˜6 Torr at a central portion of the wafer, and 6˜8 Torr at an edge portion thereof. The passivation layer may have a thickness between 5,000 to 10,000 Å.

It is to be understood that both the foregoing general description and the following detailed description of the embodiments are exemplary and explanatory and are intended to provide further explanation of the claims.

### BRIEF DESCRIPTION OF THE DRAWINGS

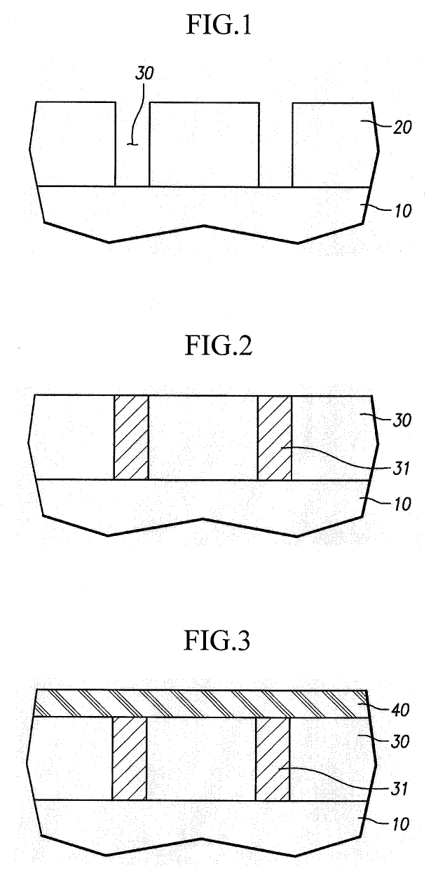

Example FIGS. 1 through 4 are cross-sectional views sequentially illustrating a method of forming a passivation layer of a semiconductor device according to embodiments.

### DETAILED DESCRIPTION

Referring to FIG. 1, an intermetal dielectric (IMD) layer 20 is formed over a substrate 10 or a lower metal layer. The intermetal dielectric layer 20 may be, for example, a tetra ethyl ortho silicate (TEOS) oxide layer.

A photoresist pattern is formed over the intermetal dielectric layer 20 for forming a via hole. Thereafter, the intermetal dielectric layer 20 is etched using the photoresist pattern as a mask to form a via hole 30.

Referring to FIG. 2, metal is deposited in the via holes 30 to form a via 31. The metal formed in the via 31 may be, for example, aluminum (Al) or tungsten (W).

Referring to FIG. 3, a metal layer is formed over the substrate 10 including the via 31. Thereafter, the metal layer is etched using a photolithography process to form a metal line 40.

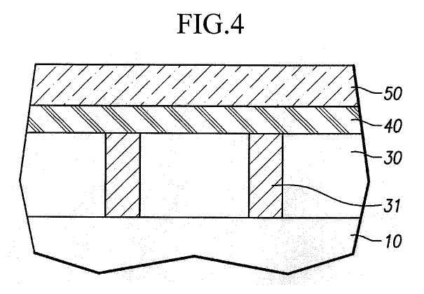

Referring to FIG. 4, a passivation layer 50 is formed over the substrate 10 including the metal line 40. The passivation layer 50 may be an SiO₂ layer formed using a high density plasma chemical vapor deposition (HDP CVD)process.

The oxide layer (SiO₂) may have a thickness ranging from 5,000 to 10,000 Å.

The passivation layer 50 is formed by a wafer cooling gas flow which has a temperature adjusted within a range of 300 to 350° C. Here, the wafer cooling gas (He) flow is 4˜6 Torr at a central portion of a wafer, and is 6˜8 Torr at an edge portion thereof.

When the passivation layer forming temperature is 380° C. or higher, voids may occur in the metal line. For this reason, the passivation layer 50 is formed at a proper temperature ranging from 300 to 350° C.

When the passivation layer 50 is formed in the above-described manner, an adhesion characteristic thereof is improved, and cracks through the layer may be prevented from occurring. Accordingly, lowering of a yield and reliability caused by the layer cracks can be prevented.

As described so far, the method of forming a passivation layer of a semiconductor device according to embodiments may improve the adhesion characteristics of the passivation layer and prevent a layer crack by controlling the wafer cooling gas flow in the HDP CVD process and thus adjusting an oxide-layer forming temperature to 300˜350° C.

Also, the method of forming the passivation layer of a semiconductor device according to embodiments may contribute to preventing yield and reliability deterioration caused by passivation layer cracks.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method of forming a passivation layer of a semiconductor device, the method comprising:
forming an intermetal dielectric layer over a lower metal layer of a semiconductor device;
forming a via in the intermetal dielectric layer;
forming a metal line on the via; and
forming a passivation layer over the substrate including the metal line, the passivation layer being formed at a temperature between approximately 300° C. to approximately 350° C. by a high density plasma chemical vapor deposition process.

2. The method according to claim 1, wherein the passivation layer is an oxide (SiO₂) layer.

3. The method according to claim 1, wherein the temperature is adjusted by controlling a cooling gas flow to a wafer in the high density plasma chemical vapor deposition process.

4. The method according to claim 3, wherein the cooling gas flow of the wafer is between about 4 Torr and about 6 Torr at a central portion of the wafer, and about 6 Torr and about 8 Torr at an edge portion thereof.

5. The method according to claim 1, wherein the passivation layer has a thickness between about 5,000 Å to about 10,000 Å.

6. A method of forming a passivation layer of a semiconductor device, the method comprising:
forming a passivation layer over a semiconductor device including an intermetal dielectric layer and a metal line, the passivation layer being formed at a temperature between about 300° C. to about 350° C. by a high density plasma chemical vapor deposition process.

7. The method according to claim 6, wherein the passivation layer is an oxide (SiO₂) layer.

8. The method according to claim 6, wherein a cooling gas flow to a wafer between about 4 Torr to about 6 Torr at a central portion of the wafer, and about 6 Torr to about 8 Torr at an edge portion of the wafer in the high density plasma chemical vapor deposition process.

9. The method according to claim 6, wherein the passivation layer has a thickness between about 5,000 Å to about 10,000 Å.
